(19) United States
(12) Patent Application Publication
(10) Pub. No.: US 2008/0076242 A1
(43) Pub. Date: Mar. 27, 2008

(54) Method of fabricating nonvolatile memory device

(75) Inventors: Sung-Gon Choi, Osan-si (KR); Hyun-Khe Yoo, Suwon-si (KR); Bo-Young Seo, Suwon-si (KR); Chang-Min Jeon, Yongin-si (KR); Ji-Do Ryu, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/893,063

(22) Filed: Aug. 14, 2007

(30) Foreign Application Priority Data
Sep. 22, 2006 (KR) 10-2006-0092478

(51) Int. Cl. H01L 21/3205

(52) U.S. Cl. 438/588; 257/E21.294

(57) ABSTRACT

A method of fabricating a nonvolatile memory device includes preparing a semiconductor substrate having a cell array region and a peripheral circuit region. Cell gate patterns are formed in the cell array region, and peripheral gate patterns are formed in the peripheral circuit region. Each of the cell gate patterns includes a control gate pattern and a capping pattern, and each of the peripheral gate patterns has a smaller thickness than the cell gate pattern. An interlayer dielectric layer is formed on the resultant structure having the cell gate patterns and the peripheral gate patterns. The interlayer dielectric layer is planarized by etching until the top surface of the capping pattern is exposed, so that an interlayer dielectric pattern is formed. The interlayer dielectric pattern covers the peripheral circuit region and fills a space between the cell gate patterns. An ion implantation process is performed using the interlayer dielectric pattern as an ion mask so that impurity ions are selectively implanted into the control gate pattern.

This application relies for priority upon Korean Patent Application No. 10-2006-0092478, filed in the Korean Intellectual Property Office on Sep. 22, 2006, the contents of which are herein incorporated by reference in their entirety.

### BACKGROUND OF THE INVENTION

1. Field of the Invention

The present invention relates to a method of fabricating a semiconductor device, and more particularly, to a method of fabricating a nonvolatile memory device.

2. Description of the Related Art

Nonvolatile memory devices can retain stored data irrespective of whether the power supply for the devices is actively applied to the devices. In general, nonvolatile memory devices may be classified as gate type or source type devices according to the type of an information storage. Specifically, read only memories (ROMs), erasable and programmable ROMs (EPROMs), and electrically erasable and programmable ROMs (EEPROMs) employ gate patterns for storing data, and thus, they are categorized as gate-type nonvolatile memory devices. By comparison, magnetic random access memories (MRAMs), ferroelectric RAMs (FRAMs), and phase-change RAMs (PRAMs) employ magnetic tunnel junctions (MTJs), ferroelectric capacitors, and phase-change patterns, respectively, which are additionally formed on source regions to store data. Thus, MRAMs, FRAMs and PRAMs are categorized as source-type nonvolatile memory devices.

A gate-type nonvolatile memory device typically includes a charge storage element and a control electrode, which are sequentially stacked on a channel region. In this case, an amount of charge stored in the charge storage element determines a threshold voltage of a memory cell transistor. That is, when a predetermined read voltage is applied to the control electrode, the amount of a current flowing through the channel region of the memory cell transistor may depend on the amount of charge stored in the charge storage element. The charge storage element may be an electrically isolated floating electrode formed of a conductive material or a charge trapping layer formed of an insulating material so that charges can be stored in the charge storage element.

Nonvolatile memory devices include not only memory cell transistors but also NMOS and PMOS transistors disposed in a peripheral circuit region and connected to the memory cell transistors. Silicide patterns are formed on gate electrodes, source electrodes, and drain electrodes of the NMOS and PMOS transistors to increase operating speed. Also, an advanced nonvolatile memory device adopts a dual-gate structure such that the NMOS and PMOS transistors can be surface channel transistors. Thus, a gate electrode of the NMOS transistor is formed of n-type polycrystalline silicon (poly-Si), while a gate electrode of the PMOS transistor is formed of p-type poly-Si.

However, the fabrication of the dual-gate structure involves performing ion doping processes using impurity ions of different conductivities. For this reason, when the dual-gate structure is adopted, the fabrication process of semiconductor devices becomes complicated. Nevertheless, a highly integrated advanced nonvolatile memory device necessarily requires the dual-gate structure because PMOS transistors can have better threshold voltage and punch-through characteristics.

In order to increase the integration density of semiconductor devices, there is another technical problem to be solved. With a reduction in the minimum linewidth of a pattern, the thickness of a photoresist pattern used as an etch mask to form the pattern is also decreasing due to technical restrictions in the lithographic process. However, most photoresist patterns are not completely resistant to an etching process. As a result, the photoresist patterns may be recessed during the etching process. Thus, in order to properly form a target pattern, a reduction in the thickness of the photoresist pattern should be accompanied with a reduction in the thickness of an etch-target layer.

However, nonvolatile memory devices, such as EEPROMs, include a cell gate pattern, which includes a floating electrode, a control electrode, and an inter-gate dielectric pattern interposed between the floating electrode and the control electrode, and it is difficult to reduce the thickness of the cell gate pattern for various technical reasons. That is, when the thickness of a photoresist pattern is reduced, it is difficult to form a cell gate pattern of a nonvolatile memory device. Furthermore, when the photoresist pattern is used as an etch mask, polymers, which are generated as etching byproducts, make it difficult to vertically form sidewalls of the cell gate pattern. This technical difficulty causes a wide dispersion of the electrical properties of the EEPROM.

In order to overcome the above-described drawbacks, a method of forming a hard mask pattern using a photoresist pattern and forming the cell gate pattern using the hard mask pattern may be considered. However, since the silicide pattern is formed using a self-aligned silicidation process, when the hard mask pattern is used, it is difficult to form the silicide pattern on peripheral gate patterns.

### SUMMARY OF THE INVENTION

The present invention provides a method of fabricating a nonvolatile memory device including a cell gate pattern having vertical sidewalls.

Also, the present invention provides a method of fabricating a nonvolatile memory device, which can dope a control gate pattern of a cell gate pattern with impurity ions without changing the dopant concentration of peripheral gate patterns.

According to an aspect of the present invention, there is provided a method of fabricating a nonvolatile memory device in which a control gate pattern of a cell gate pattern is selectively doped with impurity ions using a difference in height between the cell gate pattern and a peripheral gate pattern. The method includes preparing a semiconductor substrate including a cell array region and a peripheral circuit region. Cell gate patterns are formed in the cell array region, and peripheral gate patterns are formed in the peripheral circuit region. Each of the cell gate patterns includes a control gate pattern and a capping pattern, and each of the peripheral gate patterns has a smaller thickness than at least one of the cell gate patterns. An interlayer dielectric layer is formed on the resultant structure having the cell gate patterns and the peripheral gate patterns. The interlayer dielectric layer is planarized by etching until the top surface of the capping pattern is exposed, so that an interlayer dielectric pattern is formed. The interlayer dielectric pattern covers the peripheral circuit region and fills a space between the cell gate patterns. An ion implantation process is performed using the interlayer dielectric pattern as an ion mask so that impurity ions are selectively implanted into the control gate pattern.

According to an embodiment of the present invention, the interlayer dielectric pattern may be formed to cover the peripheral gate patterns in the peripheral circuit region. In this case, the thickness of the interlayer dielectric pattern formed on the peripheral gate pattern may be greater than a range of projection (Rp) of the impurity ions implanted during the ion implantation process to prevent the impurity ions from being implanted into the peripheral gate pattern. More specifically, the Rp of the impurity ions implanted during the ion implantation process may be greater than the thickness of the capping pattern and smaller than a difference in thickness between the peripheral gate pattern and the cell gate pattern.

According to an embodiment of the present invention, the formation of the cell gate patterns and the peripheral gate patterns includes sequentially forming a lower conductive pattern and an inter-gate dielectric layer in the cell array region of the semiconductor substrate. An upper conductive layer and a hard mask layer may be sequentially formed on the surface of the resultant structure having the inter-gate dielectric layer. The hard mask layer may be patterned to form a first mask pattern covering the peripheral circuit region and defining plane positions of the cell gate patterns. The upper conductive layer, the inter-gate dielectric layer, and the lower conductive pattern may be patterned using the first mask pattern as an etch mask, thereby forming the cell gate patterns. Each of the cell gate patterns may include a cell gate insulating layer, a floating gate pattern, an inter-gate dielectric pattern, the control gate pattern, and the capping pattern that are stacked sequentially. The first mask pattern may be patterned to form a second mask pattern defining positions of the peripheral gate patterns. The upper conductive layer may be patterned using the second mask pattern as an etch mask to form the peripheral gate patterns.

In one embodiment, the peripheral gate patterns comprise an n-type gate pattern and a p-type gate pattern, which constitute an NMOS transistor and a PMOS transistor, respectively. The method may further include, before forming the interlayer dielectric layer, exposing the top surfaces of the peripheral gate patterns by removing the second mask pattern from the peripheral circuit region; implanting n-type impurity ions into the n-type gate pattern; and implanting p-type impurity ions into the p-type gate pattern. The method may further include forming n-type impurity regions constituting the NMOS transistor in the semiconductor substrate on both sides of the n-type gate pattern; and forming p-type impurity regions constituting the PMOS transistor in the semiconductor substrate on both sides of the p-type gate pattern. The n-type impurity regions may be formed using the step of implanting n-type impurity ions into the n-type gate pattern. The p-type impurity regions may be formed using the step of implanting p-type impurity ions into the p-type gate pattern. The method may further include forming silicide patterns on the n-type and p-type gate patterns and the n-type and p-type impurity regions. The method may further include forming cell impurity regions in the semiconductor substrate on both sides of the cell gate pattern. In this case, the cell impurity regions may be formed using the step of forming the n-type impurity regions. The method may further include forming silicide patterns on the n-type and p-type gate patterns, the n-type and p-type impurity regions, and the cell impurity regions by performing a self-aligned silicidation process. In this case, the top surface of the cell gate pattern may be covered with the capping pattern during the self-aligned silicidation process to prevent the silicide pattern from being formed on the cell gate pattern.

According to an embodiment of the present invention, before forming the interlayer dielectric layer, the method may further include forming impurity regions in the semiconductor substrate between the cell gate patterns and the peripheral gate patterns; and forming silicide patterns on the peripheral gate patterns and the impurity regions.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1 through 12 are schematic cross-sectional views illustrating a method of fabricating a nonvolatile memory device according to an embodiment of the present invention.

### DETAILED DESCRIPTION OF PREFERRED EMBODIMENTS OF THE INVENTION

The preferred embodiments of the invention will now be described with reference to the accompanying drawings.

It will be understood that when a layer is referred to as being “on” another layer or substrate, it can be directly on the other layer or substrate, or intervening layers may also be present. In the drawings, the thicknesses of layers and regions are exaggerated for clarity. It will be understood that although the terms first and second are used herein to describe various regions, layers and/or sections should not be limited by these terms. These terms are only used to distinguish one region, layer or section from another region, layer or section. Thus, for example, a first layer discussed below could be termed a first layer without departing from the teachings of the present invention. Each embodiment described and illustrated herein includes complementary embodiments thereof.

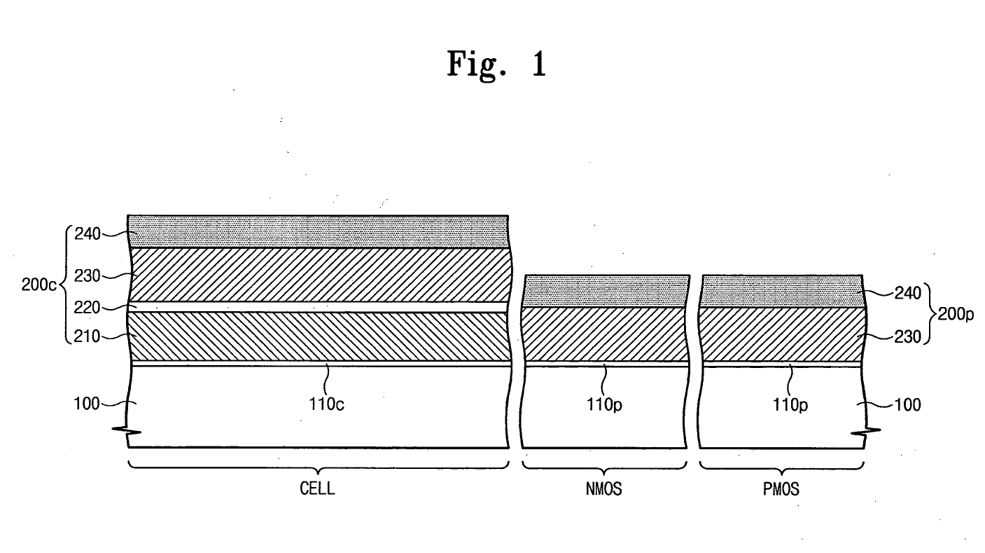

FIGS. 1 through 12 are schematic cross-sectional views illustrating a method of fabricating a nonvolatile memory device according to an embodiment of the present invention.

Referring to FIG. 1, a semiconductor substrate 100 including a cell array region CELL and a peripheral circuit region is prepared. The peripheral circuit region includes an NMOS region NMOS where an NMOSFET is formed and a PMOS region PMOS where a PMOSFET is formed.

A cell gate layer 200c is formed in the cell array region CELL, and a peripheral gate layer 200p is formed in the peripheral circuit region. The cell gate layer 200c includes a lower conductive pattern 210, an inter-gate dielectric layer 220, an upper conductive layer 230, and a hard mask layer 240 that are stacked sequentially, and the peripheral gate layer 200p includes the upper conductive layer 230 and the hard mask layer 240, which constitute the cell gate layer 200c. Furthermore, a cell gate insulating layer 110c may be formed on the semiconductor substrate 100 before forming the cell gate layer 200c, and a peripheral gate insulating layer 110p may be formed on the semiconductor substrate 100 before forming the peripheral gate layer 200p.

The formation of the lower conductive pattern 210 may include forming a lower conductive layer (not shown) on the resultant structure where the cell gate insulating layer 110c is formed. The lower conductive layer may be formed of doped polycrystalline silicon (poly-Si), more specifically, n-type poly-Si. Thereafter, the lower conductive layer is patterned to expose the top surface of the cell gate insulating layer 11c in a predetermined region of the cell array region CELL. As a result, the lower conductive layer is removed from the peripheral circuit region.

The inter-gate dielectric layer 220 may be formed of at least one of a silicon oxide layer and a silicon nitride layer. For example, the inter-gate dielectric layer 220 may include a silicon oxide layer, a silicon nitride layer, and a silicon oxide layer that are stacked sequentially. Like the lower conductive pattern 210, the inter-gate dielectric layer 220 is removed from the peripheral circuit region. Because the lower conductive pattern 210 and the inter-gate dielectric layer 220 are removed from the peripheral circuit region, a difference in thickness between the cell gate layer 200c and the peripheral gate layer 200p is substantially equal to the sum of the thicknesses of the lower conductive pattern 210 and the inter-gate dielectric layer 220. The difference in thickness between the cell gate layer 200c and the peripheral gate layer 200p is used to selectively implant impurity ions into a cell gate pattern as described herein.

The upper conductive layer 230 and the hard mask layer 240 are sequentially deposited on the entire surface of the resultant structure where the inter-gate dielectric layer 220 is formed. As a result, the upper conductive layer 230 and the hard mask layer 240 are formed in the cell region and the peripheral circuit region as described above. In an embodiment of the present invention, the upper conductive layer 230 may be formed of undoped poly-Si, and the hard mask layer 240 may include a silicon nitride layer. In another embodiment of the present invention, the hard mask layer 240 may further include other insulating layers, such as a silicon oxide layer and a silicon oxynitride layer. Also, the upper conductive layer 230 and the hard mask layer 240 may be formed using a chemical vapor deposition (CVD) technique.

The NMOSFET and PMOSFET may be categorized as either a high-voltage transistor or a low-voltage transistor, respectively, according to the thickness of the peripheral gate insulating layer 110p. In this case, the peripheral gate insulating layers 110p, which constitute the high- and low-voltage transistors, may have different thicknesses. That is, the peripheral gate insulating layer 110p of the high-voltage transistor may be thicker than that of the low-voltage transistor. In an embodiment of the present invention, the peripheral gate insulating layer 110p may be obtained using the process of forming the cell gate insulating layer 110c.

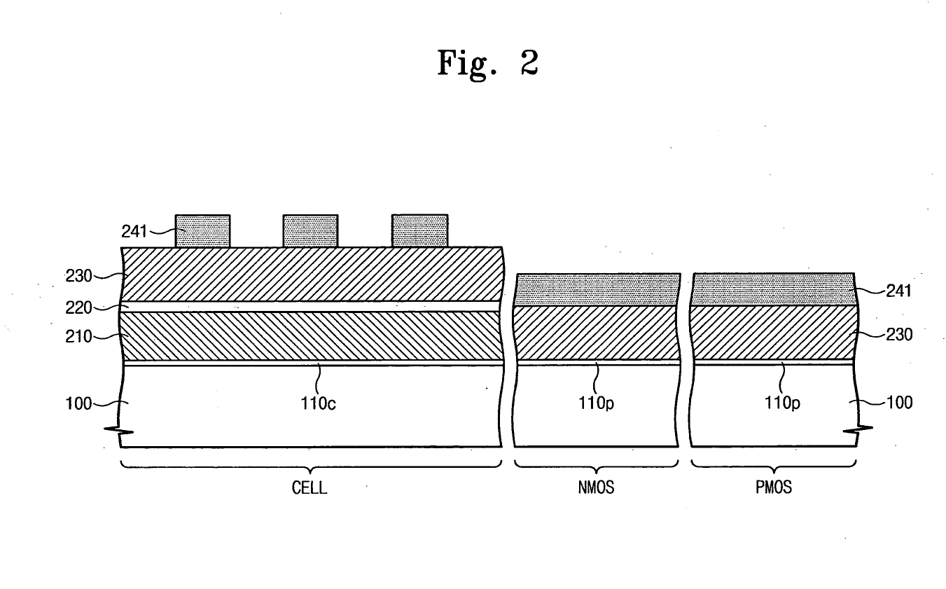

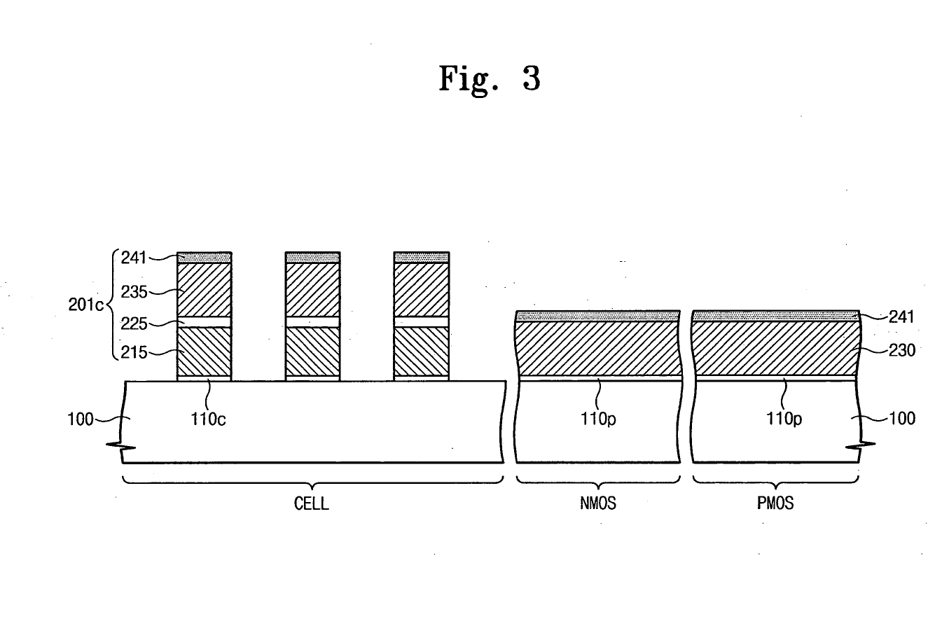

Referring to FIGS. 2 and 3, the hard mask layer 240 is patterned, thereby forming a first mask pattern 241 to selectively expose the top surface of the upper conductive layer 230 in a predetermined region of the cell array region CELL. The first mask pattern 241 defines plane positions of cell gate patterns (refer to 201c of FIG. 3). In this case, the first mask pattern 241 is formed to cover the entire surface of the peripheral circuit region.

Thereafter, as illustrated in FIG. 3, the cell gate layer 200c is patterned using the first mask pattern 241 as an etch mask, thereby forming cell gate patterns 201c to function as gate electrodes of the memory cell transistors. The cell gate pattern 201c includes a floating gate pattern 215, an inter-gate dielectric pattern 225, a control gate pattern 235, and a first mask pattern 241 that are stacked sequentially. In this case, the floating gate pattern 215, the inter-gate dielectric pattern 225, and the control gate pattern 235 are obtained by etching the lower conductive pattern 210, the inter-gate dielectric layer 220, and the upper conductive layer 230, respectively.

During the formation of the first mask pattern 241, a first photoresist pattern (not shown), which is formed using a lithography process, is used as an etch mask. A thin photoresist pattern is used due to the increase in the integration density of semiconductor devices. However, the thin photoresist pattern is not appropriate for an etch mask used for patterning the cell gate pattern 200c. However, according to the present invention, the first mask pattern 241 is used as an etch mask used for forming the cell gate patterns 201c instead of the first photoresist pattern, so that conventional technical problems can be solved. This is due to the fact that the first mask pattern 241 is formed of a silicon oxide layer or a silicon nitride layer that can minimize the generation of byproduct during the etching of the first mask pattern 241. In this case, since the first mask pattern 241 is used as an etch mask, it can be thinned out as shown in FIG. 3.

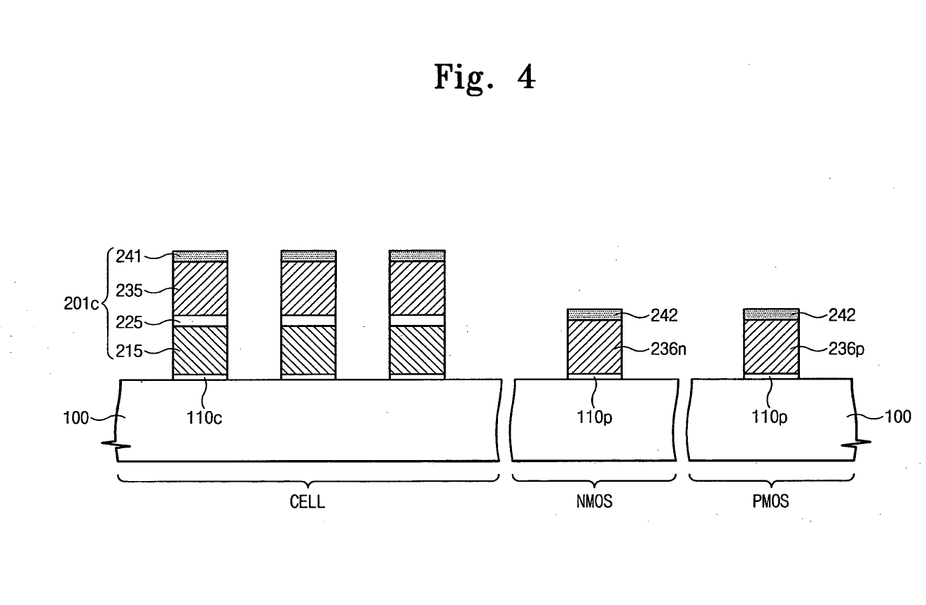

Referring to FIG. 4, the first mask pattern 241 is patterned, thereby forming a second mask pattern 242 to define plane positions of the peripheral gate patterns 236n and 236p. The formation of the second mask pattern 242 may include selectively patterning the first mask pattern 241 formed in the peripheral circuit region using a predetermined second photoresist pattern (not shown) as an etch mask. As a result, the first mask pattern 241 formed in the cell array region CELL (hereinafter, a capping pattern) is not etched and remains on top of the cell gate pattern 201c.

Thereafter, the upper conductive layer 230 is patterned using the second mask pattern 242 and the second photoresist pattern as an etch mask, thereby forming peripheral gate patterns to be used as gate electrodes of transistors constituting peripheral circuits. The peripheral gate pattern includes an n-type gate pattern 236n and a p-type gate pattern 236p, which are formed in the NMOS region NMOS and the PMOS region PMOS, respectively.

According to an embodiment of the present invention, since the upper conductive layer 230 is formed of undoped poly-Si as described above, the n-type gate pattern 236n and the p-type gate pattern 236p are formed of undoped poly-Si during the formation of the peripheral gate patterns.

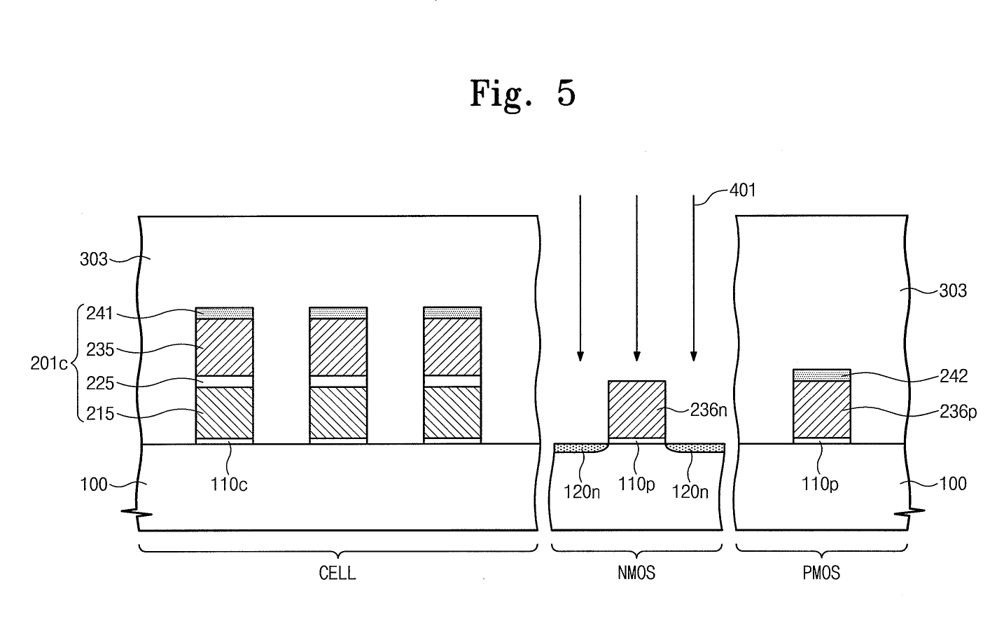

Referring to FIG. 5, a third photoresist pattern 303 is formed on the resultant structure having the peripheral gate patterns 236n and 236p to expose the NMOS region NMOS. Using the third photoresist pattern 303 as an etch mask, the second mask pattern 242 is removed from the n-type gate pattern 236n. Subsequently, a first ion implantation process 401 is performed using the third photoresist pattern 303 as an ion mask, so that low-concentrated n-type impurity ions are implanted into the n-type gate pattern 236n and the semiconductor substrate 100. As a result, low concentrated n-type impurity regions 120n are formed in the semiconductor substrate 100 on both sides of the n-type gate pattern 236n, and the n-type gate pattern 236n is doped with low concentrated impurity ions. Thereafter, the third photoresist pattern 303 is removed.

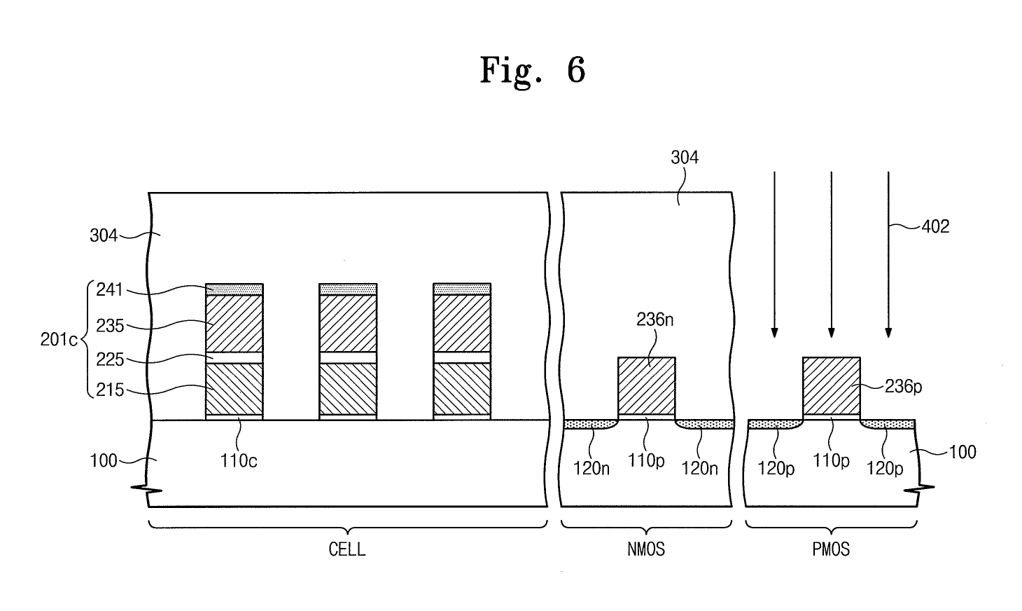

Referring to FIG. 6, a fourth photoresist pattern 304 is formed on the resultant structure from which the third photoresist pattern 303 is removed, to expose the PMOS region PMOS. Using the fourth photoresist pattern 304 as an etch mask, the second mask pattern 242 is removed from the p-type gate pattern 236p. Subsequently, a second ion implantation process 402 is performed using the fourth photoresist pattern 304 as an ion mask, so that low concentrated p-type impurity ions are implanted into the p-type gate pattern 236p and the semiconductor substrate 100. As a result, low concentrated p-type impurity regions 120p are formed in the semiconductor substrate 100 on both sides of the p-type gate pattern 236p, and the p-type gate pattern 236p is doped with low concentrated p-type impurity ions. Thereafter, the fourth photoresist pattern 304 is removed.

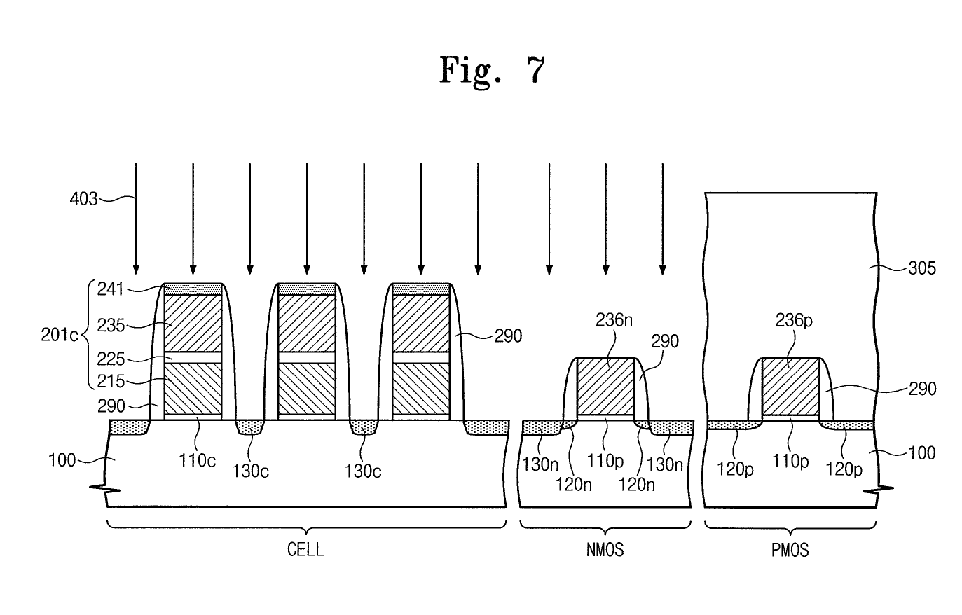

Referring to FIG. 7, after removing the fourth photoresist pattern 304, gate spacers 290 are formed on both sidewalls of the cell gate patterns 201c and the peripheral gate patterns 236n and 236p. A fifth photoresist pattern 305 is formed on the resultant structure having the gate spacers 290 to expose the cell array region CELL and the NMOS region NMOS.

A third ion implantation process 403 is performed using the fifth photoresist pattern 305 and the gate spacers 290 as an ion mask, so that high concentrated n-type impurity ions are implanted into the n-type gate pattern 236n and the semiconductor substrate 100. As a result, high concentrated n-type impurity regions 130n are formed in the semiconductor substrate 100 on both sides of the n-type gate pattern 236n, and the n-type gate pattern 236n has a sufficient dopant concentration for a gate electrode. Thereafter the fifth photoresist pattern 305 is removed.

Since the fifth photoresist pattern 305 is formed to expose the cell array region CELL, the control gate patterns 235 and their adjacent portions of the semiconductor substrate 100 are doped with high concentrated n-type impurity ions during the third ion implantation process 403. Thus, n-type cell impurity regions 130c are formed in portions of the semiconductor substrate 100 adjacent to the cell gate patterns 201c.

However, the control gate pattern 235 may not have a sufficient dopant concentration for a gate electrode of the memory cell due to the capping pattern 241. More specifically, the third ion implantation process may be performed at a low ion energy in order to prevent the cell impurity regions 130c and the high concentrated n-type impurity regions 130n from being formed to excessively great depths. As a result, impurity ions may not be sufficiently implanted into the control gate pattern 235 during the third ion implantation process 403. Thereafter, the fifth photoresist pattern 305 is removed.

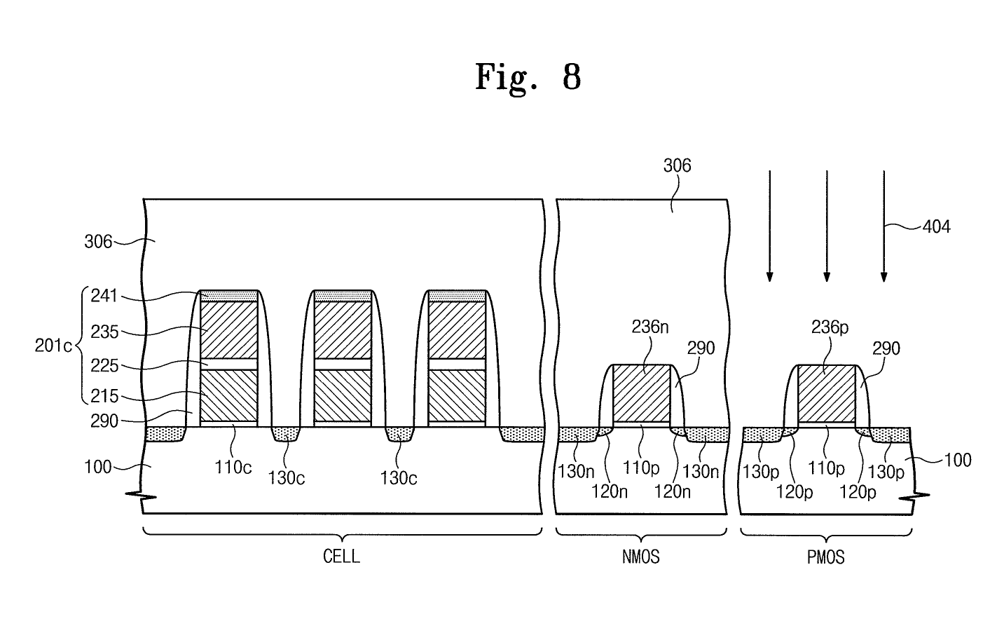

Referring to FIG. 8, a sixth photoresist pattern 306 is formed on the resultant structure from which the fifth photoresist pattern 305 is removed, to expose the PMOS region PMOS. A fourth ion implantation process 404 is performed using the sixth photoresist pattern 306 and the gate spacers 290 as an ion mask, so that high concentrated p-type impurity ions are implanted into the p-type gate pattern 236p and the semiconductor substrate 100. As a result, high concentrated p-type impurity regions 130p are formed in the semiconductor substrate 100 on both sides of the p-type gate pattern 236p, and the p-type gate pattern 236p is doped at a sufficient doped concentration for a gate electrode. Thereafter, the sixth photoresist pattern 306 is removed.

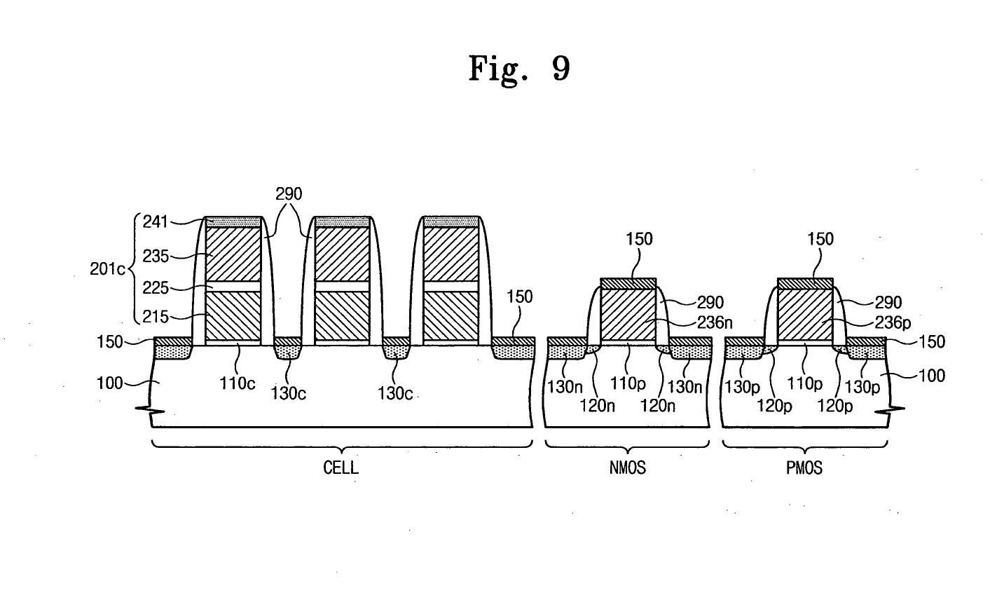

Referring to FIG. 9, by removing the sixth photoresist pattern 306, silicon is exposed on the top surface of the semiconductor substrate 100 adjacent to the cell gate patterns 201c and the peripheral gate patterns 236n and 236p and the top surfaces of the peripheral gate patterns 236n and 236p. A self-aligned silicidation process is performed to selectively form silicide patterns on the exposed silicon.

The self-aligned silicidation process includes forming a metal material layer on the resultant structure from which the sixth photoresist pattern 306 is removed and performing a predetermined annealing process to react the metal material layer with the exposed silicon. In this case, only a portion of the metal material layer that contacts the silicon is selectively silicided. Thereafter, an unsilicided portion of the metal material layer is removed. Thus, silicide patterns 150 are formed on the top surface of the semiconductor substrate 100 adjacent to the cell gate patterns 201c and the peripheral gate patterns 236n and 236p and the top surfaces of the peripheral gate patterns 236n and 236p as illustrated in FIG. 9.

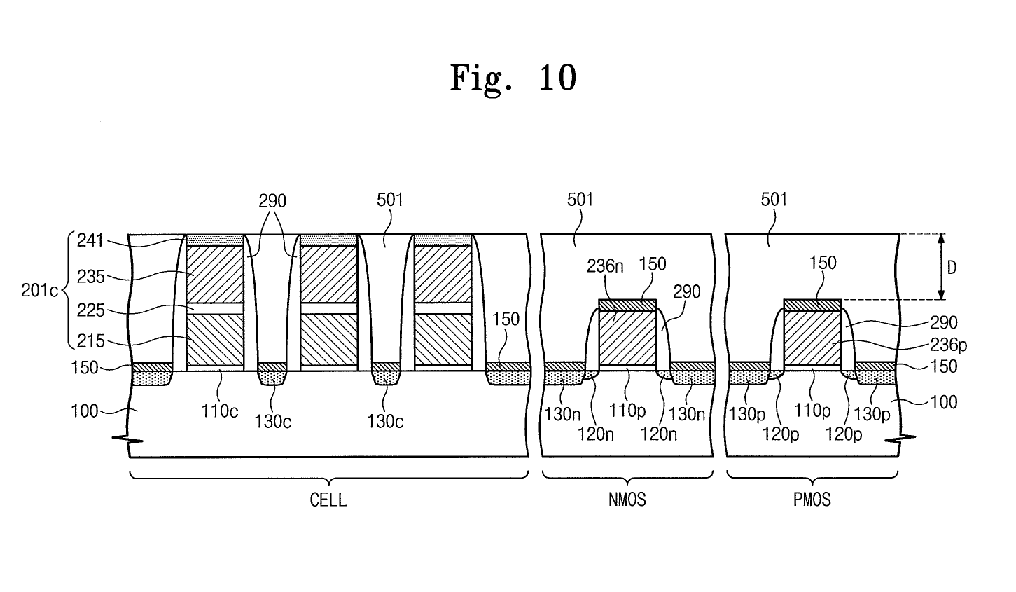

Referring to FIG. 10, a first interlayer dielectric layer is formed on the resultant structure where the silicide patterns 150 are formed, and planarized by etching until the top surface of the capping pattern 241 is exposed. Thus, a first interlayer dielectric pattern 501 is formed to fill a space between the cell gate patterns 201c. During the planarization process, the top surfaces of the peripheral gate patterns 236n and 236p are not exposed due to a height difference D between the cell gate pattern 201c and the peripheral gate patterns 236n and 236p. That is, the thickness of the first interlayer dielectric pattern 501 remaining on the peripheral gate patterns 236n and 236p corresponds to the height difference D.

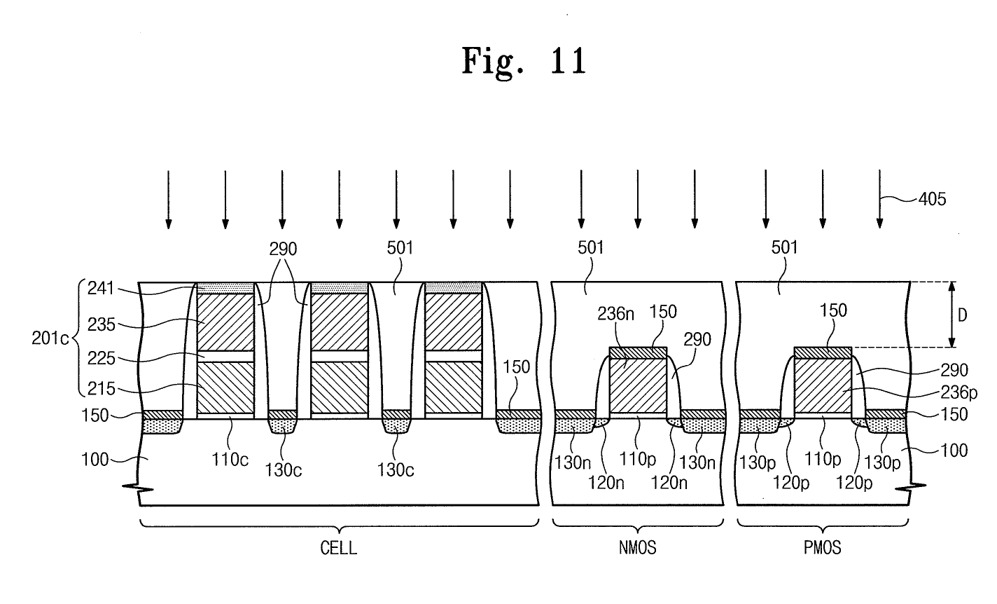

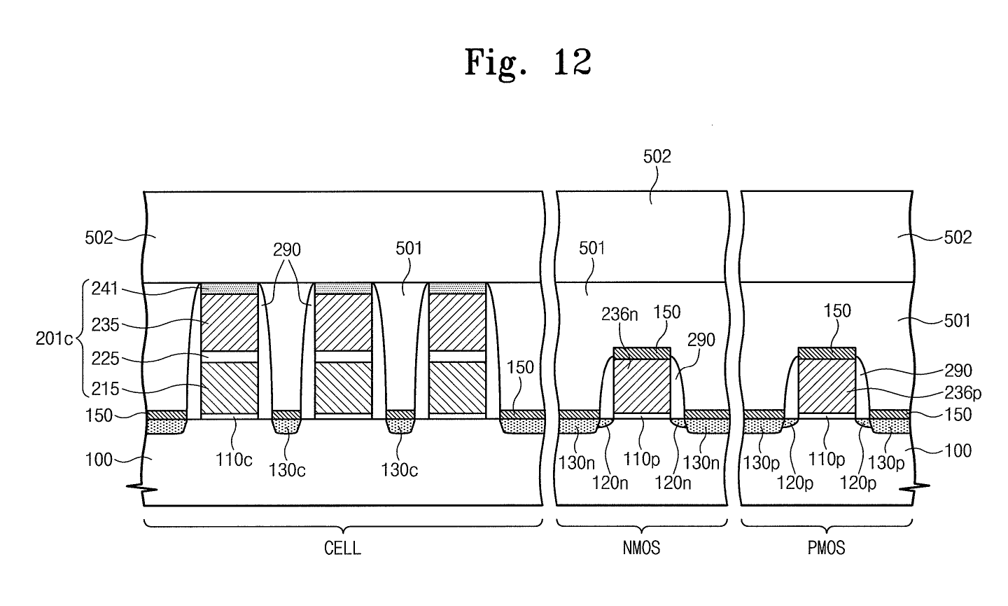

Referring to FIGS. 11 and 12, a fifth ion implantation process 405 is performed on the resultant structure where the first interlayer dielectric pattern 501 is formed, so that n-type impurity ions are implanted into the control gate electrode 235. As a result, the control gate electrode 235 can have a sufficient dopant concentration for a gate electrode of the memory cell.

Since the fifth ion implantation process 405 is performed using the first interlayer dielectric pattern 501 as an ion mask, the peripheral gate patterns 236n and 236p, in particular, the p-type gate pattern 236p, are not doped with n-type impurity ions. More specifically, the fifth ion implantation process 405 is performed under the condition that a range of projection (Rp) of impurity ions is smaller than the thickness D of the first interlayer dielectric pattern 501 remaining on the peripheral gate patterns 236n and 236p. According to the present invention, the Rp of impurity ions doped during the fifth ion implantation process 405 may be greater than the thickness of the capping pattern 241 and smaller than the height difference D between the cell gate pattern 201c and the peripheral gate patterns 236n and 236p. Thereafter, a second interlayer dielectric layer 502 is formed to cover the first interlayer dielectric pattern 501 as illustrated in FIG. 12.

In a variation of the current embodiment of the present invention, before performing the fifth ion implantation process 405, the capping pattern 241 may be removed. In this case, the fifth ion implantation process 405 may be performed under the condition that the Rp of impurity ions is smaller than the height difference D between the cell gate pattern 201c and the peripheral gate patterns 236n and 236p.

According to the present invention as described above, a cell gate pattern is formed using a hard mask. As a result, the cell gate pattern can have vertical sidewalls so that memory cells can obtain uniform electrical characteristics. Furthermore, a control gate pattern of the cell gate pattern can be selectively doped with impurity ions using a height difference between the cell gate pattern and a peripheral gate pattern without changing the dopant concentration of the peripheral gate pattern.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a nonvolatile memory device, the method comprising:
preparing a semiconductor substrate comprising a cell array region and a peripheral circuit region;
forming cell gate patterns in the cell array region and forming peripheral gate patterns in the peripheral circuit region, each cell gate pattern comprising a control gate pattern and a capping pattern, each peripheral gate pattern having a smaller thickness than at least one of the cell gate patterns;
forming an interlayer dielectric layer on the resultant structure having the cell gate patterns and the peripheral gate patterns;
forming an interlayer dielectric pattern by planarizing the interlayer dielectric layer using an etching process until the top surface of the capping pattern is exposed, the interlayer dielectric pattern covering the peripheral circuit region and filling a space between the cell gate patterns; and
selectively implanting impurity ions into the control gate pattern by performing an ion implantation process using the interlayer dielectric pattern as an ion mask.

2. The method according to claim 1, wherein the interlayer dielectric pattern is formed to cover the peripheral gate patterns in the peripheral circuit region,
wherein the thickness of the interlayer dielectric pattern formed on the peripheral gate pattern is greater than a range of projection (Rp) of the impurity ions implanted during the ion implantation process to prevent the impurity ions from being implanted into the peripheral gate pattern.

3. The method according to claim 2, wherein the Rp of the impurity ions implanted during the ion implantation process is greater than the thickness of the capping pattern and smaller than a difference in thickness between the peripheral gate pattern and the cell gate pattern.

4. The method according to claim 1, wherein forming the cell gate patterns and the peripheral gate patterns comprises:
sequentially forming a lower conductive pattern and an inter-gate dielectric layer in the cell array region of the semiconductor substrate;
sequentially forming an upper conductive layer and a hard mask layer on the surface of the resultant structure having the inter-gate dielectric layer;
forming a first mask pattern by patterning the hard mask layer, the first mask pattern covering the peripheral circuit region and defining plane positions of the cell gate patterns;
forming the cell gate patterns by patterning the upper conductive layer, the inter-gate dielectric layer, and the lower conductive pattern using the first mask pattern as an etch mask, each cell gate pattern comprising a cell gate insulating layer, a floating gate pattern, an inter-gate dielectric pattern, the control gate pattern, and the capping pattern that are stacked sequentially;
forming a second mask pattern by patterning the first mask pattern, the second mask pattern defining positions of the peripheral gate patterns; and
forming the peripheral gate patterns by patterning the upper conductive layer using the second mask pattern as an etch mask.

5. The method according to claim 4, wherein the peripheral gate patterns comprise an n-type gate pattern and a p-type gate pattern, which constitute an NMOS transistor and a PMOS transistor, respectively,
before forming the interlayer dielectric layer, the method further comprising:
exposing the top surfaces of the peripheral gate patterns by removing the second mask pattern from the peripheral circuit region;
implanting n-type impurity ions into the n-type gate pattern; and
implanting p-type impurity ions into the p-type gate pattern.

6. The method according to claim 5, further comprising:
forming n-type impurity regions constituting the NMOS transistor in the semiconductor substrate on both sides of the n-type gate pattern; and
forming p-type impurity regions constituting the PMOS transistor in the semiconductor substrate on both sides of the p-type gate pattern, wherein the n-type impurity regions are formed using the step of implanting n-type impurity ions into the n-type gate pattern,
and wherein the p-type impurity regions are formed using the step of implanting p-type impurity ions into the p-type gate pattern.

7. The method according to claim 6, further comprising forming silicide patterns on the n-type and p-type gate patterns and the n-type and p-type impurity regions.

8. The method according to claim 6, further comprising forming cell impurity regions in the semiconductor substrate on both sides of the cell gate pattern,
wherein the cell impurity regions are formed using the step of forming the n-type impurity regions.

9. The method according to claim 8, further comprising forming silicide patterns on the n-type and p-type gate patterns, the n-type and p-type impurity regions, and the cell impurity regions by performing a self-aligned silicidation process,
wherein the top surface of the cell gate pattern is covered with the capping pattern during the self-aligned silicidation process to prevent the silicide pattern from being formed on the cell gate pattern.

10. The method according to claim 1, before forming the interlayer dielectric layer, further comprising:
forming impurity regions in the semiconductor substrate between the cell gate patterns and the peripheral gate patterns; and
forming silicide patterns on the peripheral gate patterns and the impurity regions.
